(19) United States
(12) Patent Application Publication
(10) Pub. No.: US 2016/0116533 A1
(43) Pub. Date: Apr. 28, 2016

(54) DIAGNOSTIC APPARATUS

(71) Applicants: FUJITSU LIMITED, Kawasaki-shi (JP); Socionext Inc., Yokohama-shi (JP)

(72) Inventors: Tsutomu ISHIDA, Kawasaki (JP); Koji Banno, Kawasaki (JP)

(73) Assignees: FUJITSU LIMITED, Kawasaki (JP); Socionext Inc., Yokohama (JP)

(21) Appl. No.: 14/921,242

(22) Filed: Oct. 23, 2015

(30) Foreign Application Priority Data
Oct. 28, 2014 (JP) 2014-219000

(51) Int. Cl. G01R 31/3177

(52) U.S. Cl. CPC G01R 31/3177

(57) ABSTRACT

A diagnostic apparatus is disclosed, which includes a processor configured to extract, from a plurality of components included in an integrated circuit to be diagnosed, a failure candidate based on test results obtained from actual operations of the integrated circuit, the actual operations being implemented by individually applying a plurality of types of test patterns to the integrated circuit, extract, from a plurality of pass patterns of the test patterns, a pass pattern with which a signal is transmitted to the failure candidate, based on log data obtained from simulations with the test patterns, the test results of the plurality of pass patterns being normal, and execute, using a fail pattern of the test patterns and the extracted pass patterns, a failure simulation assuming that the failure candidate is failed, the test result of the fail pattern being abnormal.

### CROSS-REFERENCE TO RELATED APPLICATIONS

This present application is based upon and claims the benefit of priority of the prior Japanese Patent Application No. 2014-219000, filed on Oct. 28, 2014, the entire contents of which are incorporated herein by reference.

### FIELD

This disclosure is related to a diagnostic apparatus.

### BACKGROUND

Failure simulations are performed by using test patterns, assuming a failure in an LSI (Large-Scale Integration), to generate a failure dictionary file in which a failure assumed and a test pattern number with which the failure assumed can be detected are associated with each other (Patent Document 1, for example).

[Patent Document 1] Japanese Laid-open Patent Publication No. 03-120485

[Patent Document 2] Japanese Laid-open Patent Publication No. 07-55887

A plurality of types of test patterns that cause an integrated circuit, which is to be diagnosed, to be operated actually can be classified, using results of tests with respective test patterns, as a pass pattern whose test result is normal or a fail pattern whose test result is abnormal. Using a number of test patterns including all the pass patterns when a failure simulation for diagnosing logical failure is performed after the tests is advantageous in terms of increasing diagnosis accuracy, but disadvantageous in terms of reducing a process load.

### SUMMARY

According to one aspect of the disclosure, a diagnostic apparatus is provided, which includes a processor configured to:

extract, from a plurality of components included in an integrated circuit to be diagnosed, a failure candidate based on test results obtained from actual operations of the integrated circuit, the actual operations being implemented by individually applying a plurality of types of test patterns to the integrated circuit,

extract, from a plurality of pass patterns of the test patterns, a pass pattern with which a signal is transmitted to the failure candidate, based on log data obtained from simulations with the test patterns, the test results of the plurality of pass patterns being normal, and

execute, using a fail pattern of the test patterns and the extracted pass patterns, a failure simulation assuming that the failure candidate is failed, the test result of the fail pattern being abnormal.

The object and advantages of the embodiment will be realized and attained by means of the elements and combinations particularly pointed out in the claims. It is to be understood that both the foregoing general description and the following detailed description are exemplary and explanatory and are not restrictive of the invention.

### BRIEF DESCRIPTION OF DRAWINGS

FIG. 1 is a diagram illustrating an example of a flow of a failure diagnosis process.

FIG. 2 is a diagram illustrating an example of an output of a logic failure diagnosis.

FIG. 3 is a diagram illustrating a configuration of a diagnostic apparatus 100 according to an example.

FIG. 4 is a functional block diagram of the diagnostic apparatus 100.

FIG. 5 is a diagram illustrating an example of test pattern data 202.

FIG. 6 is a histogram illustrating an example of a relationship between the number of times being activated and the number of assumed failures.

FIG. 7 is a flowchart illustrating an example of a way of extracting a pass pattern by a first pass pattern extraction part 21.

FIG. 8 is a flowchart illustrating an example of a way of extracting a pass pattern by a second pass pattern extraction part 22.

FIG. 9 is a flowchart illustrating an example of a way of extracting a pass pattern by a third pass pattern extraction part 23.

FIG. 10 is a flowchart illustrating an example of a failure simulation way by a failure simulation part 40.

FIGS. 11A and 11B are diagrams illustrating an example of a failure simulation with a fail pattern.

FIGS. 12A and 12B are diagrams illustrating an example of a failure simulation with a pass pattern.

FIG. 13 is diagram illustrating an example of a way of calculating an activation percentage used in an activation percentage calculation part 14.

### DESCRIPTION OF EMBODIMENTS

In the following, embodiments will be described with reference to the accompanying drawings.

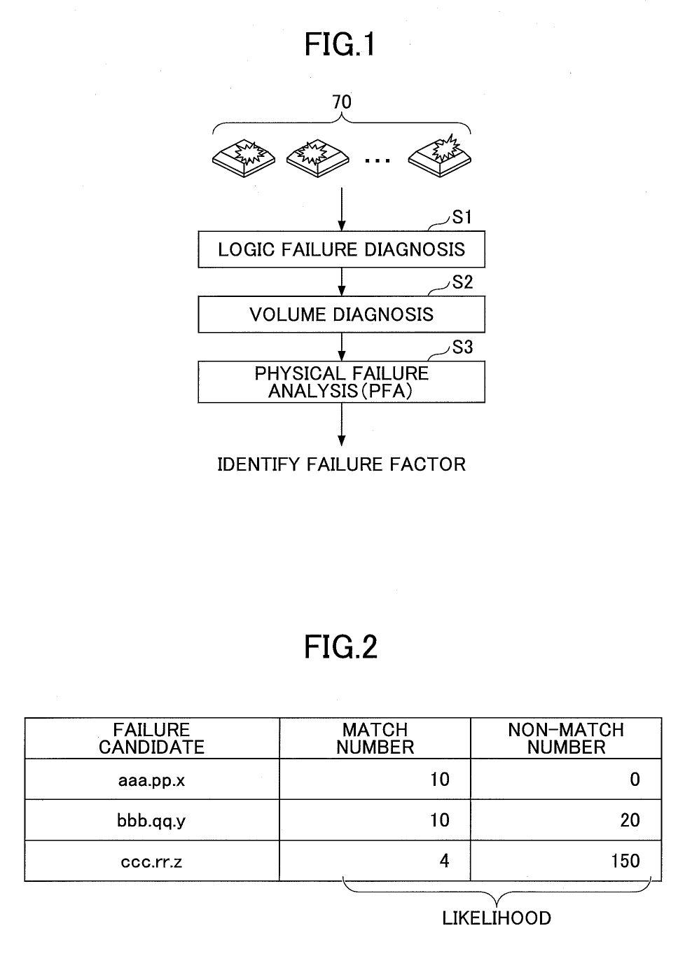

FIG. 1 is a diagram illustrating an example of a flow of a failure diagnosis process. FIG. 2 is a diagram illustrating an example of an output of a logic failure diagnosis. Here, as an example, an integrated circuit to be diagnosed is an LSI. The LSI includes a plurality of FFs (Flip Flops). In FIG. 1, a plurality of LSI chips 70 (referred to as “defective chips 70”, hereinafter) whose test results, which are obtained when test patterns are given to cause actual operations of the integrated circuit to be diagnosed, are defective.

In step S1, a test operator performs a logic failure diagnosis using a diagnostic apparatus 100 that includes a computer. The diagnostic apparatus 100 is described hereinafter. The logic failure diagnosis includes determining, for respective defective chips 70, likelihoods of failure candidates. The failure candidate is a component whose test result indicates a probability of a failure thereof, among a plurality of components of the defective chip 70, for example. The components may include a net, a cell, a pin, etc., for example. It is noted that, as an example, the term “net” indicates a signal line from one pin to another pin (or other pins) between which there is no cell. The term “cell” indicates an AND gate, an OR gate, etc. The term “pin” indicates a pin that is connected to an input or output of the cell. The failure candidate may be expressed and identified with a net name, a cell name, etc., as illustrated in FIG. 2, for example. The likelihood is an index value that indicates a probability that the failure candidate has actually failed. The likelihood includes a match number and a non-match number. The match number and the non-match number are described hereinafter. Further, a way of diagnosing the logical failure is described hereinafter.

In step S2, the test operator performs a volume diagnosis, using a computer, to estimate a failure factor, etc., with a statistical analysis. As a result of this, an estimation result indicating that “via at a second layer”, for example, is a factor of the failure can be obtained. The volume diagnosis may be implemented by the computer used for the diagnostic apparatus 100 or another computer. A way of the volume diagnosis may be arbitrary, and may be such as disclosed in Japanese Laid-open Patent Publication No. 2012-163357, for example, the entire contents of which are hereby incorporated by reference.

In step S3, the test operator performs a physical failure analysis to physically analyze the failure factor, etc. When the test operator observes this, such a result that “an error in parameters of a manufacturing apparatus” is the factor of the failure, for example, can be obtained.

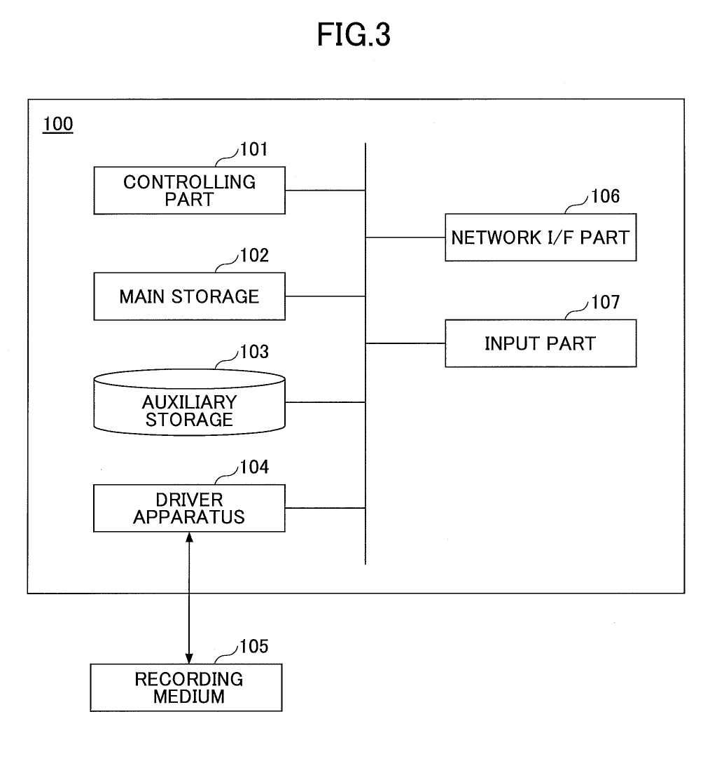

FIG. 3 is a diagram illustrating a configuration of the diagnostic apparatus 100 according to an example.

As illustrated in FIG. 3, the diagnostic apparatus 100 includes a controlling part 101, a main storage 102, an auxiliary storage 103, a driver apparatus 104, a network I/F part 106, and an input part 107.

The controlling part 101 is an arithmetic unit which executes programs stored in the main storage 102 or the auxiliary storage 103. The controlling part 101 receives the data from the input part 107 or the storage and outputs to the storage after performing the calculation or processing.

The memory device 102 may be a ROM (Read Only Memory), a RAM (Random Access Memory) or the like. The memory device 102 stores programs and data, such as an Operating System, which is basic software executed by the controlling part 101, application software, etc.

The auxiliary storage 103 is a HDD (Hard Disk Drive) or the like. The auxiliary storage 103 stores data related to the application software, etc.

The driver apparatus 104 reads the programs from a recording medium 105, for example, a flexible disk, and installs the programs in the storage.

The recording medium 105 stores a predetermined program. The program stored in the recording medium 105 is installed in the diagnostic apparatus 100 via the driver apparatus 104. The installed program can be executed by the diagnostic apparatus 100.

The network I/F part 106 is an interface between peripherals with communication capabilities, which are connected via a network constructed of data transmission lines such as wired and/or wireless transmission lines, and the diagnostic apparatus 100.

The input part 107 may include a keyboard including cursor keys, number keys and function keys, a mouse, a touch pad or the like.

It is noted that, in the example illustrated in FIG. 3, the processes described hereinafter can be implemented by causing the diagnostic apparatus 100 to execute one or more programs. Further, it is also possible to store one or more programs in the recording medium 105, and cause the diagnostic apparatus 100 to read the programs stored in the recording medium 105 to implement the processes described hereinafter. It is noted that the recording medium 105 may be of any type. For example, the recording medium 105 may include a recording medium for optically, electrically or magnetically storing information, such as a CD (Compact Disc)-ROM, a flexible disk, a magneto-optical disk, and a semiconductor memory for electrically storing information, such as a ROM and a flash memory. It is noted that carrier waves are not included in a concept of the term “recording medium”.

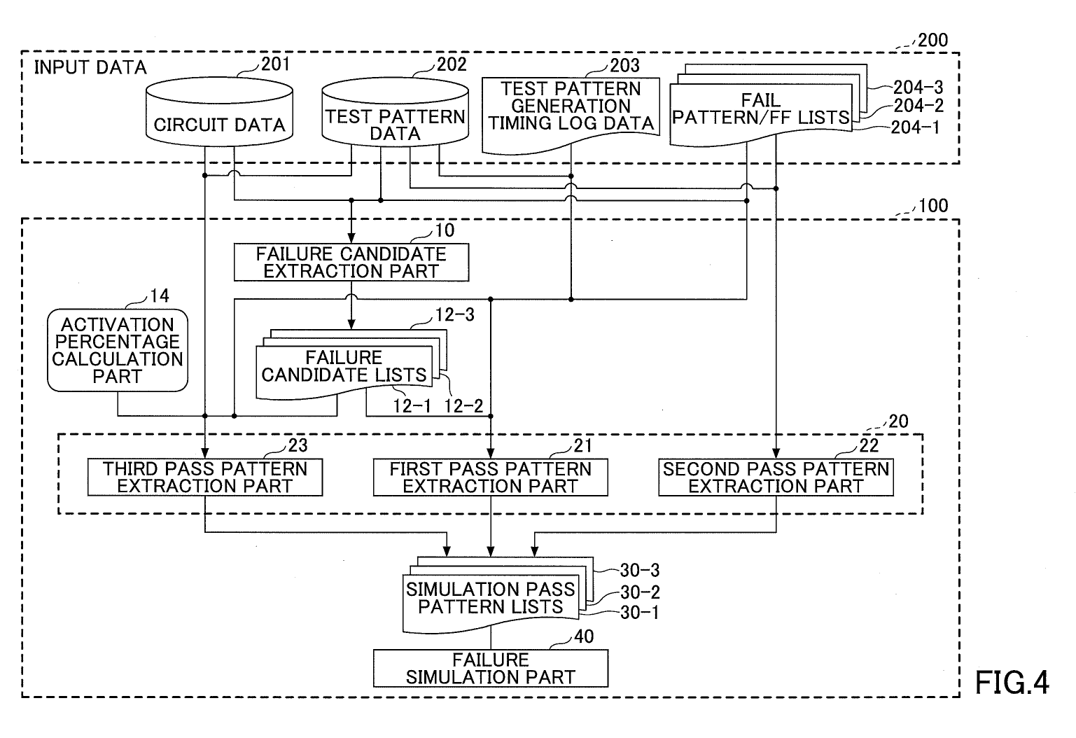

FIG. 4 is a functional block diagram of the diagnostic apparatus 100. In FIG. 4, data (lists) such as input data 200 is also illustrated. It is noted that, in the following, for the sake of reducing complexity of explanation, unless otherwise specified, it is assumed that the LSI chips (simply referred to as “chips”, hereinafter) to be diagnosed are of the same type. In other words, a functional block diagram illustrated in FIG. 4 is related to a certain type. The certain type may be arbitrary. In the case where a plurality of types are to be diagnosed, functional block diagrams illustrated in FIG. 4 are implemented for the types, respectively. It is noted that, in FIG. 4, the lists indicated by reference numerals followed by numerals after hyphens, such as fail pattern/FF lists 204-1, 204-2, 204-3, for example, mean that the lists exist for chips, respectively. In the following explanation, the numerals after hyphens are not used.

In the following explanation, the verb “test” means actually applying a test pattern to the chip (i.e., causing the chip to actually operate with the test pattern), and does not mean a simulation with the test pattern. The phase “simulation with the test pattern” is substantially the same as the phase “generating the test pattern”. Further, the failure simulation differs from the simulation with the test pattern in that the failure simulation is performed with an assumption that a particular failure candidate is failed while the simulation with the test pattern is performed without such assumption.

The input data 200 can be input via the input part 107 and the recording medium 105 illustrated in FIG. 3. The input data 200 thus input may be stored in the auxiliary storage 103 illustrated in FIG. 3.

The input data 200 includes circuit data 201, test pattern data 202, test pattern generation timing log data 203, and fail pattern/FF lists 204.

The circuit data 201 is related to the LSI chips to be diagnosed. The circuit data 201 may be based on design data. The circuit data 201 may be in form of Verilog HDL source codes. In the case where there are a plurality of types of the chips, the circuit data 201 may include data related to the respective types.

The test pattern data 202 is related to all types of the test patterns used for testing, for example. Specifically, there are a plurality of types of test patterns that may form the test pattern data 202. At the time of testing, the test patterns are individually applied to the respective chips. It is noted that, as a result of testing, all the test pattern of the test pattern data 202 can be classified as a fail pattern or a pass pattern described hereinafter.

It is noted that, at the time of testing, a part of the prepared test patterns may be sampled to be used. In such a case, for the sake of reducing the complexity of the explanation, the test pattern data 202 includes only the test patterns that are sampled to be used for testing. Thus, in the following, the term “test pattern” indicates the test pattern in the test pattern data 202 (i.e., the test pattern that is used for testing). However, the test pattern data 202 may include the test pattern that is not used for testing.

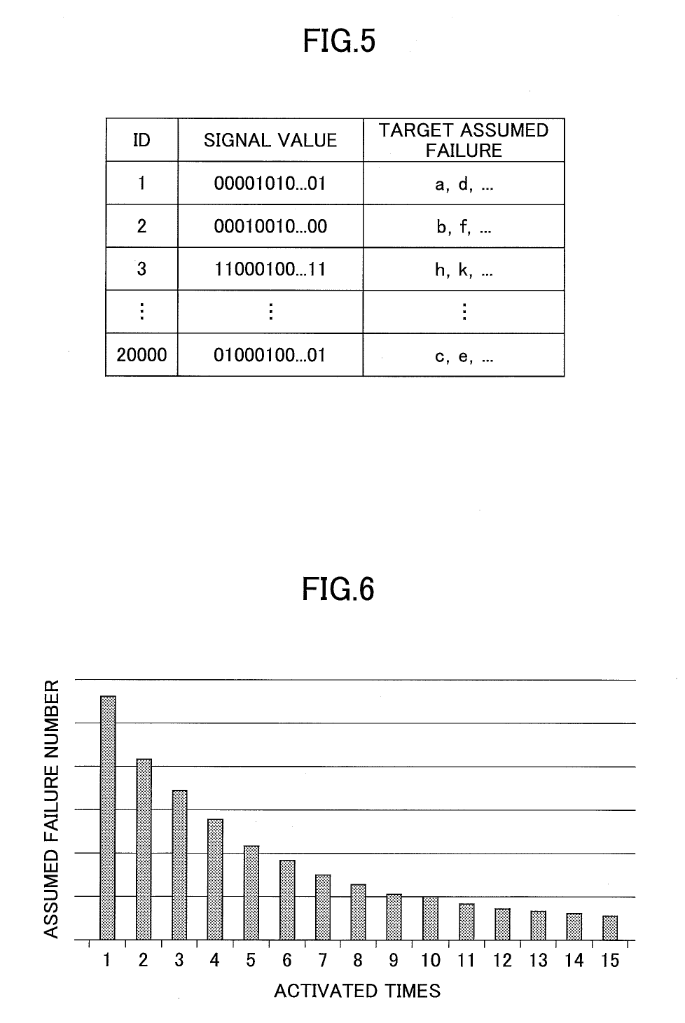

The test pattern data 202 may include, for each test pattern, ID (Identification) numerals, signal values, and target assumed failures. The signal values, which form the test pattern, are a series of a value 0 or 1 for respective FFs in the chips. The target assumed failure represents the target of the assumed failure to which a signal is transmitted with the corresponding test pattern. There are target assumed failures for the test patterns, respectively. The target assumed failure is a part of the assumed failures to which the signal is to be transmitted with the corresponding test pattern in theory. The phase “in theory” means “in the simulation with the test pattern”. In FIG. 5, the respective assumed failures are expressed with lower case letters; however, the respective target assumed failures may be expressed in other ways. The assumed failures are all the components that could be the failure candidate in the chip and assumed to be failed at the time of the failure simulation described hereinafter. The respective test patterns are generated such that any assumed failure in the chip has the signal transmitted thereto with at least any one of the test patterns in theory. It is noted that the failure candidate is included in the assumed failures.

The test pattern generation timing log data 203 is generated at the time of generating all the test patterns in the test pattern data 202. Generating the test pattern involves the simulation with the test pattern, and the simulation result with the test pattern generates the log data. The test pattern generation timing log data 203 includes information for identifying the target assumed failures (see FIG. 5) of the respective test patterns. Further, the test pattern generation timing log data 203 may include information for identifying all the assumed failures to which the signals are to be transmitted in theory for the respective test patterns.

The fail pattern/FF lists 204 represent relationships between fail patterns and the FFs in which the abnormality is detected. A plurality of the chips are tested with the respective test patterns, and the fail pattern/FF lists 204 are generated separately for the respective chips. Specifically, the fail pattern/FF lists 204 are generated based on the test results of the respective test patterns on a chip basis. The fail pattern is a test pattern whose test result, when actually applied to the chip, is abnormal. The fact that the test result is abnormal means that an output value of the FF is different from its expected value (theoretical value). The FF in which the abnormality is detected is a FF whose output value is different from its expected value. For the respective fail patterns, there is at least one FF in which the abnormality is detected. In the following, the FFs in the fail pattern/FF lists 204 in which the abnormality is detected are referred to as“a failed FF”. In the following, as an example, it is assumed that the fail pattern/FF list 204 related to a certain chip includes a plurality of the fail patterns.

The diagnostic apparatus 100 includes a failure candidate extraction part 10, an activation percentage calculation part 14, a pass pattern extraction part 20, and a failure simulation part 40. The pass pattern extraction part 20 includes a first pass pattern extraction part 21, a second pass pattern extraction part 22, and a third pass pattern extraction part 23. The failure candidate extraction part 10, the activation percentage calculation part 14, the pass pattern extraction part 20 and the failure simulation part 40 can be implemented by the controlling part 101 illustrated in FIG. 3.

The failure candidate extraction part 10 extracts the failure candidate, based on the circuit data 201, the test pattern data 202 and the fail pattern/FF lists 204, to generate failure candidate lists 12. The failure candidate lists 12 are generated separately on a chip basis, using the fail pattern/FF lists 204 related to the corresponding chips. A way of extracting the failure candidate by the failure candidate extraction part 10 is arbitrary. With respect to a certain failed FF, one or more components (failure candidates) that could be a factor of the abnormality of the FF can be identified from the fail pattern.

The activation percentage calculation part 14 determines an activation percentage. The activation percentage indicates a probability that, with respect to a certain assumed failure, the signal is transmitted to the assumed failure in theory when the simulation is performed with an arbitrary test pattern. A way of determining the activation percentage is arbitrary. For example, the activation percentage calculation part 14 may determine (calculate) the activation percentage based on the data in the test pattern generation timing log data 203. FIG. 6 is a histogram illustrating an example of a relationship between the number of times being activated (activated times) and the number of assumed failures (assumed failure number). In FIG. 6, the number of times being activated is the number of the transmissions of the signals that have been transmitted to a certain assumed failure in theory. The histogram is generated based on the data related to the sampled test patterns in the test pattern generation timing log data 203, for example. It is noted that the sampled test patterns may be all the test patterns in the test pattern generation timing log data 203. In FIG. 6, if the number of the assumed failures associated with the number of times being activated “2” is “N”, for example, it means that there are N assumed failures which are activated twice when the sampled test patterns are applied. For example, with respect to 1000 test patterns, if the histogram indicates that the signals are transmitted to 90 percent or more of all the assumed failures 10 times or more in theory, the activation percentage may be 1% (=10/1000*100). In this case, the activation percentage that can cover 90 percent of the assumed failures is calculated. It is noted that the 90 percent is an example and a different value may be used. In the following, such a way of calculating the activation percentage is referred to as “a first activation percentage calculation way”. Alternatively, the activation percentage may be calculated as an average value based on the data related to the sampled test patterns in the test pattern generation timing log data 203, for example. In the following, such a way of calculating the activation percentage is referred to as “a second activation percentage calculation way”. In this case, the average value of the activation percentage P_{AC} can be calculated with the following formula (1).

$${P}_{AC} = \frac{{\sum }_{i = 2}^{n} fi}{n m} \qquad ( 1 )$$

Here, n is the number of the sampled test patterns, m is the number of the assumed failures in the circuit in the chip, and fi is the number of the assumed failures that have been activated with the test pattern i. For example, with respect to the histogram illustrated in FIG. 6, it is assumed that the number of the test patterns is “1000”, and the number of the assumed failures in the circuit in the chip is “2000000”. In this case, the average value of the activation percentage can be calculated with the following formula (2).

$${P}_{AC} = \frac{\sum \begin{matrix}( assumed failure number of respective bars in histogram ) \times \\ ( activated times )\end{matrix}}{1000 \times 2000000} \qquad ( 2 )$$

The activation percentage thus determined is used in the third pass pattern extraction part 23. This is described hereinafter. It is noted that the activation percentage calculation part 14 may selectively use the first or second activation percentage calculation way according to the types of the chips. This is described hereinafter.

The pass pattern extraction part 20 extracts particular pass patterns from all the test patterns in the test pattern data 202, on a chip basis, to generate simulation pass pattern lists 30. The simulation pass pattern lists 30 are generated separately for the respective chips. The particular pass patterns are part of the pass patterns in the test pattern data 202.

The first pass pattern extraction part 21 extracts the pass patterns with which the signals are transmitted to the respective failure candidates, from all the pass patterns, based on a failure candidate lists 12, the test pattern data 202 and the test pattern generation timing log data 203. The first pass pattern extraction part 21 extracts the pass patterns, using the corresponding failure candidate lists 12, for the respective chips. Thus, the first pass pattern extraction part 21 extracts, on a chip basis, the test patterns with which the signals are transmitted to the respective failure candidates in the corresponding failure candidate lists 12. Here, the log data in the test pattern generation timing log data 203 includes the information for identifying the target assumed failure, as described above. Thus, the first pass pattern extraction part 21 may extract the pass patterns whose target assumed failures correspond to the failure candidates in the corresponding failure candidate lists 12. Further, the log data in the test pattern generation timing log data 203 may include information for identifying all the assumed failures to which the signals are to be transmitted in theory for the respective test patterns. In this case, the first pass pattern extraction part 21 may extract the pass patterns whose assumed failures correspond to the failure candidates in the corresponding failure candidate lists 12.

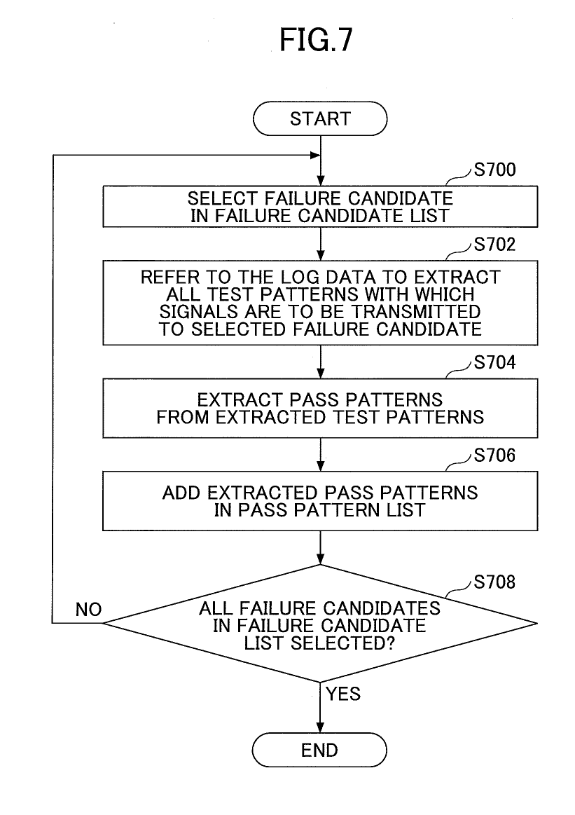

FIG. 7 is a flowchart illustrating an example of a way of extracting a pass pattern by the first pass pattern extraction part 21. The process illustrated in FIG. 7 is performed on a chip basis.

In step S700, the first pass pattern extraction part 21 selects a certain failure candidate in the failure candidate list of the corresponding chip. The order in which the failure candidate is selected is arbitrary.

In step S702, the first pass pattern extraction part 21 refers to the log data in the test pattern generation timing log data 203 to extract, from the test patterns in the test pattern data 202, all the test patterns with which the signals are to be transmitted to the failure candidate selected in step S700.

In step S704, the first pass pattern extraction part 21 extracts all the pass patterns from the extracted test patterns. The first pass pattern extraction part 21 may determine, based on the fail pattern/FF lists 204, whether the test pattern is a pass pattern.

In step S706, the first pass pattern extraction part 21 adds the pass patterns extracted in step S704 in the simulation pass pattern list 30 related to the corresponding chip.

In step S708, the first pass pattern extraction part 21 determines whether all the failure candidates in the failure candidate list of the corresponding chip have been selected. If it is determined that all the failure candidates in the failure candidate list of the corresponding chip have been selected, the process routine ends, otherwise the process routine returns to step S700 to select another failure candidate.

According to the process illustrated in FIG. 7, the pass patterns with which the signals are to be transmitted to the respective failure candidates in the failure candidate lists are extracted, and the extracted pass patterns are added in the simulation pass pattern lists 30. In this way, the pass patterns are accumulated in the simulation pass pattern lists 30 by the first pass pattern extraction part 21. With this arrangement, it becomes possible to extract the pass patterns with which the signals are to be transmitted to the failure candidates from a number of the pass patterns, and accumulate the extracted pass patterns in the simulation pass pattern lists 30.

The second pass pattern extraction part 22 extracts, from all the pass patterns, the pass patterns whose similarities to the fail patterns are greater than or equal to a predetermined reference, based on the circuit data 201 and the fail pattern/FF lists 204. The second pass pattern extraction part 22 extracts the pass patterns, using the corresponding failure candidate lists 12, for the respective chips. Thus, the second pass pattern extraction part 22 extracts, on a chip basis, the test patterns whose similarities to the fail patterns in the corresponding failure candidate lists 12 are greater than or equal to the predetermined reference. The second pass pattern extraction part 22 extracts, on a fail pattern basis, for the fail patterns in the corresponding failure candidate lists 12, the pass patterns which are similar to the corresponding fail patterns. Here, the pass pattern that is similar to the fail pattern tends to have a higher probability that the signal is to be transmitted to the failure candidate related to the fail pattern because of its similarity to the fail pattern. For this reason, the predetermined reference is set such that the probability that the signal is to be transmitted to the failure candidate related to the fail pattern is sufficiently high.

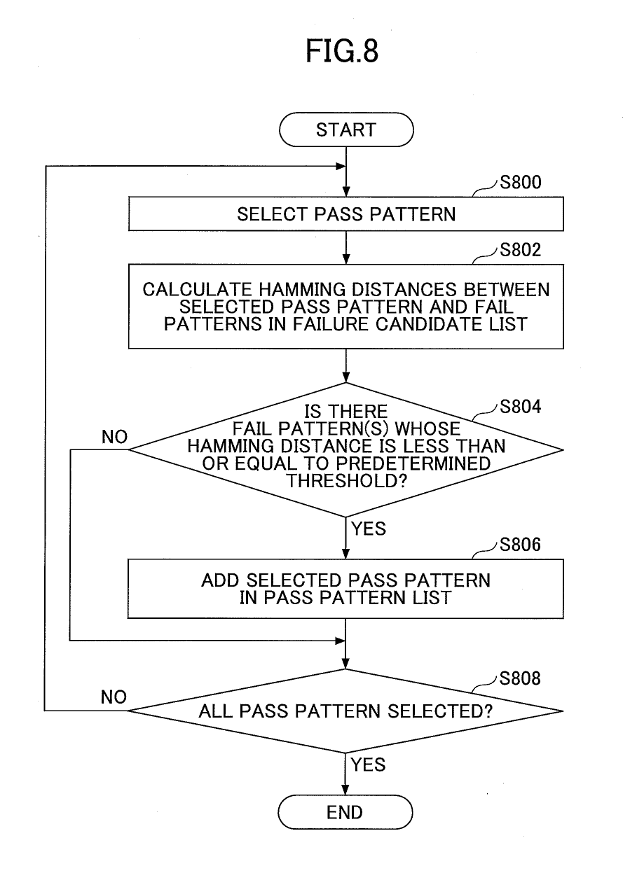

FIG. 8 is a flowchart illustrating an example of a way of extracting the pass pattern by the second pass pattern extraction part 22. The process illustrated in FIG. 8 is performed on a chip basis.

In step S800, the second pass pattern extraction part 22 selects a certain pass pattern from all the pass patterns related to the corresponding chip in the test pattern data 202. The order in which the pass pattern is selected is arbitrary. The second pass pattern extraction part 22 may determine, based on the fail pattern/FF lists 204, whether the test pattern in the test pattern data 202 is a pass pattern.

In step S802, the second pass pattern extraction part 22 calculates hamming distances between the pass pattern selected in step S800 and the respective fail patterns in the failure candidate list. The hamming distance may be calculated on a fail pattern basis, for example. In this case, the number of the hamming distances the second pass pattern extraction part 22 calculates corresponds to the number of the fail patterns. In calculating the hamming distance between the pass pattern and a certain fail pattern, the second pass pattern extraction part 22 uses the whole fail pattern or a part of the fail pattern. The part of the fail pattern may be obtained by removing “don't care term” inserted at the time of generating the fail pattern (test pattern), for example. Alternatively, the second pass pattern extraction part 22 may calculate the hamming distance with respect to a pattern part that is common to the respective fail patterns in the corresponding failure candidate list.

In step S804, the second pass pattern extraction part 22 determines whether there is any fail pattern whose hamming distance calculated in step S802 is less than or equal to a predetermined threshold D1. It is noted that, in the case where the hamming distance with respect to the pattern part common to the respective fail patterns in the corresponding failure candidate list is calculated in step S802, the second pass pattern extraction part 22 determines whether the calculated hamming distance is less than or equal to the predetermined threshold D1. The predetermined threshold D1 is a reference value for determining whether the probability that the pass pattern causes the signal to be transmitted to the failure candidate related to the fail pattern is high. The predetermined threshold D1 may be an adapted value. For example, the predetermined threshold D1 may be “10”. If it is determined that there is any fail pattern whose hamming distance is less than or equal to the predetermined threshold D1, the process routine goes to step S806, otherwise the process routine goes to step S808.

In step S806, the second pass pattern extraction part 22 adds the pass pattern selected in step S800 in the simulation pass pattern list 30 related to the corresponding chip.

In step S808, the second pass pattern extraction part 22 determines whether all the pass patterns related to the corresponding chip have been selected. If it is determined that all the pass patterns have been selected, the process routine ends, otherwise the process routine returns to step S800 to select another pass pattern.

According to the process illustrated in FIG. 8, only the pass patterns whose hamming distances with respect to the fail patterns are small are extracted from all the pass patterns to be added in the simulation pass pattern lists 30. In this way, the pass patterns are accumulated in the simulation pass pattern lists 30 by the second pass pattern extraction part 22. With this arrangement, it becomes possible to extract the pass patterns, with which the signals are to be transmitted to the failure candidates with high probability, from a number of the pass patterns, and accumulate the extracted pass patterns in the simulation pass pattern lists 30.

The third pass pattern extraction part 23 randomly extracts, based on the activation percentage from the activation percentage calculation part 14 and the test pattern data 202, from all the pass patterns, the pass patterns whose number is such that the signals are expected to be transmitted to the respective failure candidates predetermined times or more. The predetermined times is arbitrary as long as it is greater than or equal to 1. The greater the predetermined times becomes, the higher the load becomes. The predetermined times may be an adapted value. In the following, as an example, the predetermined times is “1”.

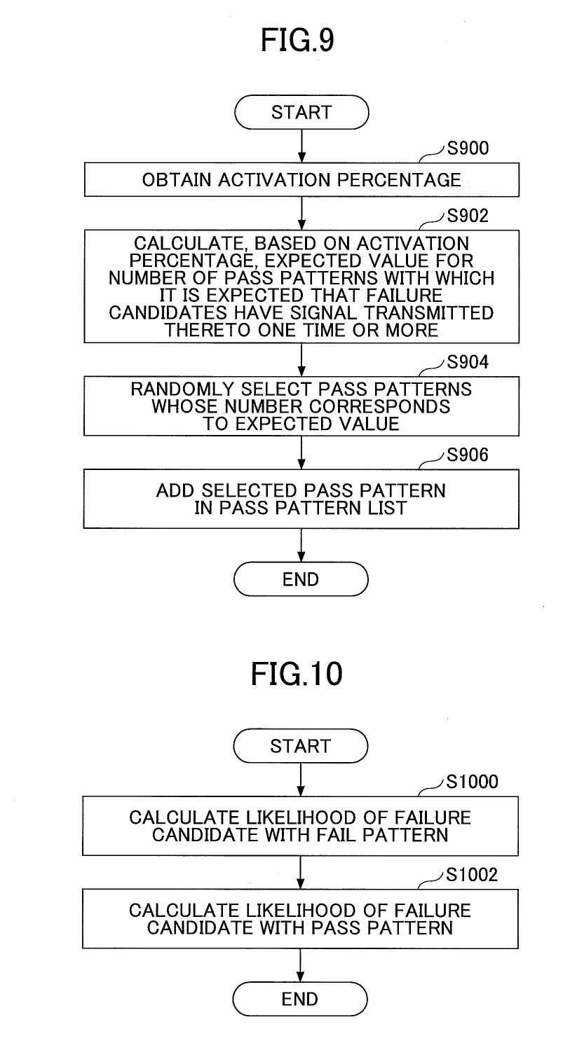

FIG. 9 is a flowchart illustrating an example of a way of extracting the pass pattern by the third pass pattern extraction part 23. The process illustrated in FIG. 9 is performed on a chip basis.

In step S900, the third pass pattern extraction part 23 obtains the activation percentage from the activation percentage calculation part 14. It is noted that the activation percentages determined by the activation percentage calculation part 14 as described above may be stored in a predetermined memory (the auxiliary storage 103 illustrated in FIG. 3, for example) on a type basis. In this case, the third pass pattern extraction part 23 reads the activation percentage with respect to the type of the corresponding chip from the memory.

In step S902, the third pass pattern extraction part 23 calculates, based on the activation percentage obtained in step S900, an expected value for the number of the pass patterns with which it is expected that all the failure candidates in the failure candidate list of the corresponding chip have the signal transmitted thereto one time or more. The expected value may be calculated with the following formula (3).

$${\sum }_{k = 0}^{l - 1} \frac{1}{1 - {( 1 - \frac{P}{100} )}^{l - k}} \qquad ( 3 )$$

Where 1 is the number of all the failure candidates in the failure candidate list of the corresponding chip, and P is the activation percentage [%]. For example, it is assumed that the number of all the failure candidates is “20, and the activation percentage is 1%. In this case, the expected value is calculated using the formula (3) as follows.

$${\sum }_{k = 0}^{19} \frac{1}{1 - {( 1 - \frac{99}{100} )}^{20 - k}} = 368.1 \qquad formula ( 4 )$$

In step S904, the third pass pattern extraction part 23 randomly selects the pass patterns whose number corresponds to the expected value calculated in step S902, from all the pass patterns of the corresponding chip in the test pattern data 202. The number corresponding to the expected value is near the expected value, and may be a minimum integer greater than or equal to the expected value, for example. For example, in the case where the expected value is “368.1” as indicated by the formula (4) described above, the third pass pattern extraction part 23 randomly selects the 369 pass patterns, from all the pass patterns of the corresponding chip in the test pattern data 202. Alternatively, the number corresponding to the expected value may be a value obtained by subtracting, from the minimum integer greater than or equal to the expected value, the number of the pass patterns accumulated by the first pass pattern extraction part 21 and the second pass pattern extraction part 22. A way of randomly selecting the pass patterns is arbitrary.

In step S906, the third pass pattern extraction part 23 adds the pass pattern selected in step S904 in the simulation pass pattern list 30 related to the corresponding chip.

According to the process illustrated in FIG. 9, the pass patterns whose number is determined such that the signals are expected to be transmitted to the respective failure candidates in the failure candidate lists one time or more are extracted from all the pass patterns, and the extracted pass patterns are added in the simulation pass pattern lists 30. In this way, the pass patterns are accumulated in the simulation pass pattern lists 30 by the third pass pattern extraction part 23. With this arrangement, it becomes possible to extract the pass patterns of the number, with which it can be expected that the signals are to be transmitted to the failure candidates one time or more, from a number of the pass patterns, and accumulate the extracted pass patterns in the simulation pass pattern lists 30.

The failure simulation part 40 performs the failure simulation, on a chip basis, to calculate the likelihoods of the respective failure candidates. At that time, the failure simulation part 40 performs the failure simulation, using all the fail patterns related to the corresponding chip and all the pass patterns in the simulation pass pattern lists 30 related to the corresponding chip. With this arrangement, the process load can be reduced due to the reduced number of the pass patterns to be used, compared to a configuration in which all the fail and pass patterns related to the corresponding chip are used. Further, according to the embodiment, the respective pass patterns in the simulation pass pattern lists 30 are not pass patterns extracted randomly with the random number, but pass patterns extracted such that the respective failure candidates have the signal transmitted thereto one time or more. Thus, according to the embodiment, it becomes possible to increase the accuracy of the calculated likelihoods of the failure candidates, compared to a configuration in which the number of the pass patterns, which are extracted randomly, is random. A way of performing the failure simulation by the failure simulation part 40 is arbitrary. Specifically, the details of the way are arbitrary, as long as the failure simulation is performed using only all the fail patterns related to the corresponding chip and all the pass patterns in the simulation pass pattern lists 30 related to the corresponding chip. For example, the failure simulation may be performed as disclosed in Patent Document 1 or Patent Document 2 described above.

FIG. 10 is a flowchart illustrating an example of a failure simulation (logic failure diagnosis) way by the failure simulation part 40. The process illustrated in FIG. 10 is performed on a chip basis.

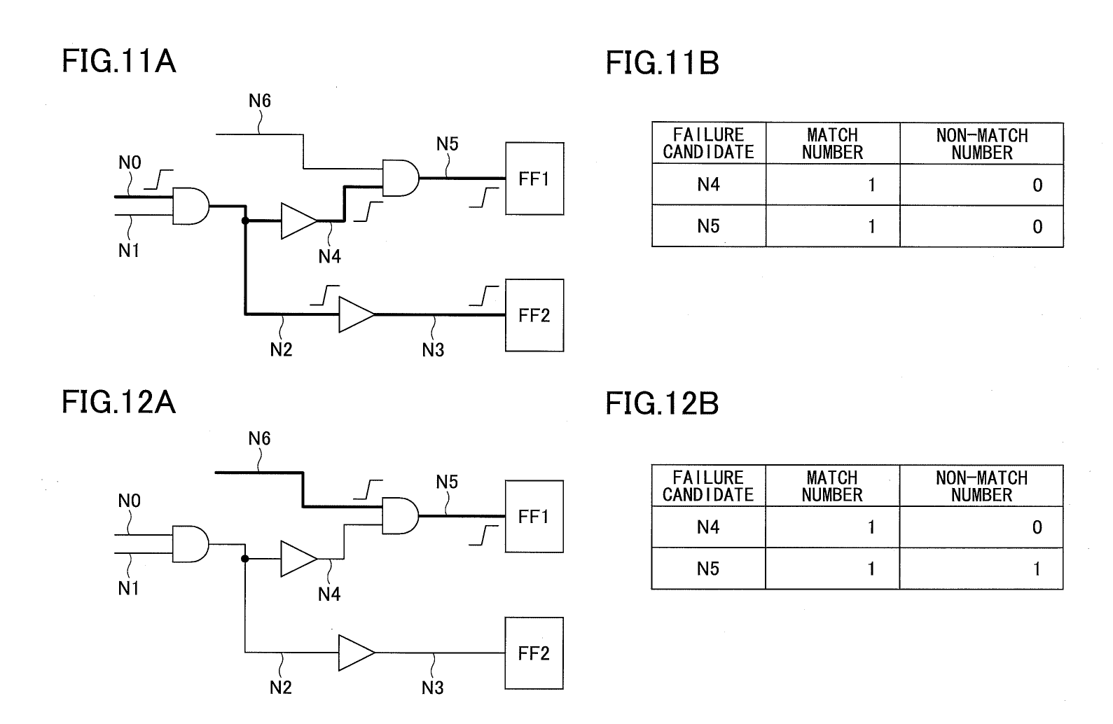

In step S1000, the failure simulation part 40 performs the failure simulation, using all the fail patterns related to the corresponding chip, to calculate the likelihoods of the failure candidates. Here, as an example, the likelihoods of the failure candidates include the match number and the non-match number. The match number is the number of the failed FFs in which the abnormality is detected at the time of testing and whose results of the failure simulation are also abnormal when the failure simulation is performed assuming a certain failure candidate (an assumed failure related to the failure candidate) is failed. The non-match number is the number of the failed FFs in which the abnormality is not detected at the time of testing but whose results of the failure simulation are abnormal when the failure simulation is performed assuming a certain failure candidate is failed. FIGS. 11A and 11B are diagrams illustrating an example of the failure simulation using the fail pattern. FIG. 11A schematically illustrates a part of the circuit of the chip, and FIG. 11B illustrates the calculation result of the likelihoods of the failure candidates. In the example illustrated in FIG. 11A, it is assumed that the failed FF corresponding to a certain fail pattern in the fail pattern/FF list 204 is the FF1. The nets in the circuit part illustrated in FIG. 11A to which the signal is to be transmitted with the fail pattern (test pattern) are nets N0, N2, N3, N4 and N5 which are illustrated with bold lines. In the example illustrated in FIG. 11A, since the failed FF is the FF1, the nets N4 and N5 are the failure candidates. When the failure simulation is performed with the illustrated fail pattern, assuming that the net N4 (assumed failure) is failed, the fact that the FF1 is the failed FF is consistent with the fact that the FF1 is the failed FF according to the fail pattern. Thus, in this case, the match number of the net N4 is incremented by “1”, as illustrated in FIG. 11B. Further, similarly, when the failure simulation is performed with the illustrated fail pattern, assuming that the net N5 (assumed failure) is failed, the fact that the FF1 is the failed FF is consistent with the fact that the FF1 is the failed FF according to the fail pattern. Thus, in this case, the match number of the net N5 is incremented by “1”, as illustrated in FIG. 11B.

In step S1002, the failure simulation part 40 performs the failure simulation, using all the pass patterns in the simulation pass pattern list 30 related to the corresponding chip, to calculate the likelihoods of the failure candidates. FIGS. 12A and 12B are diagrams illustrating an example of the failure simulation using the pass pattern. FIG. 12A schematically illustrates a part of the circuit of the chip, and FIG. 12B illustrates the calculation result of the likelihoods of the failure candidates. The nets in the circuit part illustrated in FIG. 12A to which the signal is to be transmitted with the pass pattern (test pattern) are nets N6 and N5 which are illustrated with bold lines. When the failure simulation is performed with the illustrated pass pattern, assuming that the net N5 (assumed failure) is failed, the fact that the FF1 is the failed FF is not consistent with the fact that the FF1 is not the failed FF according to the pass pattern. Thus, in this case, the non-match number of the net N5 is incremented by “1”, as illustrated in FIG. 12B.

According to the process illustrated in FIG. 10, the failure simulation part 40 performs the failure simulation, using all the fail patterns and all the pass patterns in the simulation pass pattern lists 30. The failure simulation part 40 calculates, on a failure candidate basis, total values of the likelihoods of the failure candidates obtained by the respective failure simulations. With this arrangement, it becomes possible to reduce the process load, compared to a configuration in which all the pass patterns related to the corresponding chip are used. Further, the respective pass patterns in the simulation pass pattern lists 30 are extracted such that the respective failure candidates have the signal transmitted thereto one time or more. Thus, according to the embodiment, it becomes possible to increase the accuracy of the calculated likelihoods of the failure candidates, compared to a configuration in which the number of the pass patterns, which are extracted randomly, is random.

It is noted that the diagnostic apparatus 100 may perform a process for narrowing the final failure candidates based on the likelihoods of the respective failure candidates calculated by the failure simulation part 40. For example, the diagnostic apparatus 100 may remove, from the final failure candidates, the failure candidate whose non-match number exceeds a predetermined value. Further, the diagnostic apparatus 100 may select, as the final failure candidates, the failure candidates whose match number exceeds a predetermined value.

It is noted that in the embodiment described above, it is assumed that the chips to be diagnosed are of the same type; however, the calculation way of the activation percentage, the calculation way of the similarity, and/or the predetermined threshold D1 may be varied according to the types of the chips.

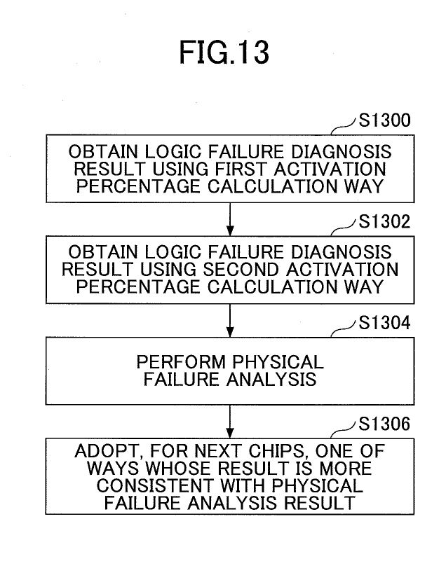

FIG. 13 is diagram illustrating an example of a way of calculating the activation percentage used in the activation percentage calculation part 14. The way illustrated in FIG. 13 may be performed for only the first chip (or the predetermined number of chips from the beginning), among the chips of the same type to be diagnosed, on a type basis, for example.

In step S1300, the test operator obtains the logic failure diagnosis result from the diagnostic apparatus 100, using the first activation percentage calculation way. According to the first activation percentage calculation way, the activation percentage which can cover 90% of the assumed failures, for example, is calculated, as described above.

In step S1302, the test operator obtains the logic failure diagnosis result from the diagnostic apparatus 100, using the second activation percentage calculation way. According to the second activation percentage calculation way, the average value of the activation percentages of all the assumed failure is calculated, as described above.

In step S1304, the test operator performs the physical failure analysis to determine whether the logic failure diagnosis result obtained in step S1300 or the logic failure diagnosis result obtained in step S1302 is consistent with the physical failure analysis result.

In step S1306, the test operator adopts one of the first and second activation percentage calculation ways whose result is more consistent with the physical failure analysis result than the other's for the subsequent chips of the same types.

According to the way of determining the activation percentage calculation way illustrated in FIG. 13, when there are two activation percentage calculation ways, one of these activation percentage calculation ways which is more consistent with the physical failure analysis result than the other is adopted, which can increase the reliability of the logic failure diagnosis result. The way of determining the activation percentage calculation way illustrated in FIG. 13 is suited for a case where appropriate activation percentage calculation way may differ between the types.

It is noted that, in the example illustrated in FIG. 13, there are two activation percentage calculation ways; however, the same holds true for the case where there are three or more activation percentage calculation ways. Further, instead of or in addition to the activation percentage calculation way, the calculation way of the similarity and/or the predetermined threshold D1 used in the second pass pattern extraction part 22 may be varied according to the types of the chips such that the logic failure diagnosis result is consistent with the physical failure analysis result.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

For example, according to the embodiments described above, the pass pattern extraction part 20 includes three pass pattern extraction parts, that is to say, the first pass pattern extraction part 21, the second pass pattern extraction part 22 and the third pass pattern extraction part 23; however, this is not indispensable. For example, the pass pattern extraction part 20 may include only one or two of the first pass pattern extraction part 21, the second pass pattern extraction part 22 and the third pass pattern extraction part 23.

What is claimed is:

1. A diagnostic apparatus, comprising a processor configured to:
extract, from a plurality of components included in an integrated circuit to be diagnosed, a failure candidate based on test results obtained from actual operations of the integrated circuit, the actual operations being implemented by individually applying a plurality of types of test patterns to the integrated circuit,
extract, from a plurality of pass patterns of the test patterns, a pass pattern with which a signal is transmitted to the failure candidate, based on log data obtained from simulations with the test patterns, the test results of the plurality of pass patterns being normal, and
execute, using a fail pattern of the test patterns and the extracted pass patterns, a failure simulation assuming that the failure candidate is failed, the test result of the fail pattern being abnormal.

2. The diagnostic apparatus of claim 1, wherein the processor extracts, from all the pass patterns of the test patterns, the pass patterns with which signals are transmitted to the failure candidate.

3. A diagnostic apparatus, comprising a processor configured to:
extract, from a plurality of components included in an integrated circuit to be diagnosed, a failure candidate based on test results obtained from actual operations of the integrated circuit, the actual operations being implemented by individually applying a plurality of types of test patterns to the integrated circuit,
extract, from a plurality of pass patterns of the test patterns, a pass pattern whose similarity with respect to a fail pattern is greater than or equal to a predetermined reference, the test results of the plurality of pass patterns being normal, the test result of the fail pattern being abnormal, and
execute, using the fail pattern and the extracted pass patterns, a failure simulation assuming that the failure candidate is failed.

4. The diagnostic apparatus of claim 3, wherein the processor calculates hamming distances between the fail pattern and each of the pass patterns, and extracts, from the pass patterns, the pass pattern whose hamming distance is less than a predetermined threshold.

5. The diagnostic apparatus of claim 4, wherein, when there are a plurality of the fail patterns, the processor extracts, for each of the fail patterns, the pass pattern whose hamming distance is less than the predetermined threshold.

6. A diagnostic apparatus, comprising a processor configured to:
extract, from a plurality of components included in an integrated circuit to be diagnosed, a failure candidate based on test results obtained from actual operations of the integrated circuit, the actual operations being implemented by individually applying a plurality of types of test patterns to the integrated circuit,
randomly extract, from a plurality of pass patterns of the test patterns, pass patterns whose number corresponds to an expected value required for a signal to be transmitted to the failure candidate one or more times, and
execute, using a fail pattern of the test patterns and the extracted pass patterns, a failure simulation assuming that the failure candidate is failed, the test result of the fail pattern being abnormal.

7. The diagnostic apparatus of claim 6, wherein the processor calculates the expected value based on a probability that the simulation with an arbitrary one of the test patterns causes the signal to be transmitted to the failure candidate.

8. The diagnostic apparatus of claim 7, wherein the processor calculates the probability based on log data obtained from simulations with the test patterns.

9. The diagnostic apparatus of claim 8, wherein the processor calculates the probability based a histogram based on the log data, the histogram representing, with respect to a plurality of components of the integrated circuit, a relationship between the number of the transmissions of the signals that have been transmitted to the components and the number of the components to which the signals have been transmitted.

10. The diagnostic apparatus of claim 9, wherein the processor calculates the probability by dividing B by M, M being the number of the test patterns, B being the number of the transmissions of the signals that have been transmitted to the components, obtained by the histogram, the number of the components to which the signals have been transmitted B times or more being greater than or equal to a predetermined proportion of a total number of the components.

11. The diagnostic apparatus of claim 1, wherein the processor calculates a likelihood of a failure of the failure candidate based on an execution result of the failure simulation.

12. The diagnostic apparatus of claim 3, wherein the processor calculates a likelihood of a failure of the failure candidate based on an execution result of the failure simulation.

13. The diagnostic apparatus of claim 6, wherein the processor calculates a likelihood of a failure of the failure candidate based on an execution result of the failure simulation.

14. The diagnostic apparatus of claim 1, wherein the components included in the integrated circuit include a net, a cell and a pin.

15. The diagnostic apparatus of claim 3, wherein the components included in the integrated circuit include a net, a cell and a pin.

16. The diagnostic apparatus of claim 6, wherein the components included in the integrated circuit include a net, a cell and a pin.
